(19) United States
(12) Patent Application Publication
(10) Pub. No.: US 2006/0111858 A1
(43) Pub. Date: May 25, 2006

(54) Computer method and apparatus for online process identification

(76) Inventor: Yucai Zhu, Best (NL)

Correspondence Address: Yucai Zhu, Grensheuvel 10, Best, 5685AG, NL

(21) Appl. No.: 11/261,642

(22) Filed: Oct. 31, 2005

Related U.S. Application Data
(63) Continuation of application No. 60/629,703, filed on Nov. 22, 2004.

(51) Int. Cl. G01D 18/00; G01R 35/00

(52) U.S. Cl. 702/85

(57) ABSTRACT

A computer method and apparatus of online automated model identification of multivariable processes is disclosed. The method and apparatus carries out automatically all the four basic steps of industrial process identification: 1) identification test signal design and generation, 2) identification plant test, 3) model identification and 4) model validation. During the automated plant test, process models will be automatically generated at a given time interval, for example, every hour, or on demand; the ongoing test can be automatically adjusted to meet the process constraints and to improve the data quality. Plant test can be in open loop operation, closed-loop operations or partly open loop and partly closed-loop. In a (partial) closed-loop plant test, any type of controller can be used which include proportional-integral-derivative (PID) controllers and any industrial model predictive controller (MPC). The obtained process models can be used as the model in advanced process controllers such as model predictive control (MPC) and linear robust control; they can also be used as inferential models or soft sensors in prediction product qualities. The apparatus can be used in new MPC controller commissioning as well as in MPC controller maintenance.

### FIELD OF THE INVENTION

The present invention is a computer method and apparatus for online automatic identification of dynamic models of industrial processing units, particularly in the process industries such as refining, petrochemical, chemical, steel, food, pulp and paper and utilities. The invention can deal with large-scale process units with many manipulated variables (MVs) and controlled variables (CVs); the number of MVs can be over 50 and the number of CVs over 100. Models obtained using the computer method and apparatus are used in model predictive control (MPC) and other advanced process control (APC); they can also be used for inferential modelling or soft sensor that provide prediction of product qualities that are too costly to measure frequently.

### BACKGROUND OF THE INVENTION

Model predictive control (MPC) has become a standard technology of advanced process control (APC). MPC technology has gained its industrial position in refinery and petrochemical industries (Qin and Badgwell, 1997) and is beginning to attract interest from other process industries. Dynamic models play a central role in the MPC technology. Typically, identified linear models are used in an MPC controller. Industrial experience has shown that the most difficult and time-consuming work in an MPC project is plant testing and model identification (Richalet, 1993). Moreover, in MPC maintenance, the main task is model identification. Traditional identification plant tests are called step tests, which reflect the fact that each manipulating variable (MV) is stepped separately and some clear step responses are expected for modelling each transfer function. The step test time is very long, which occupies much manpower and makes project planning difficult. The tests are done manually, which dictates extremely high commitment of the engineers and operators; such tests are usually carried out around the clock for several weeks when testing refinery and petrochemical processing units such as crude units, FCCUs, delayed cokers and ethylene units. The quality of collected data depends heavily on the technical competence and experience of the control engineer and the operator. After the test, it can take another few weeks to analyse the data and to identify the models. This is because that traditional identification software packages use trial-and-error approach and there are many user entered parameters. The high cost of model identification has hindered wider application of the MPC technology.

### SUMMARY OF THE INVENTION

The present invention is a computer method and apparatus for online automatic identification of dynamic models of industrial processing units for use in model predictive control (MPC) and other advanced process control (APC). The computer apparatus consists of two major parts:
1) A testing device that generates test signals, carries out the plant test automatically by writing the test signals to testing variables and collects process data; and
2) A model identification device that carries model identification automatically using collected process data available at the moment, validate models and provide adjustment for the ongoing test.

The two parts are connected seamlessly for the user so that the whole identification procedure is done online and automatically. However, if necessary, each part can also be executed separately and manual intervention is also possible.

This section describes briefly how the invention works in an MPC environment. Assume that a user is going to commission or re-commission an MPC controller. He will develop process models using process identification. He has done some pre-test on the unit and he also obtained process knowledge from operation personals, so that he knows the dominant time to steady state (settling time) and proper step sizes (amplitudes) for manipulating variables (MVs) for the plant test.

Based on pre-test information and process knowledge, the user has constructed a so-called Expectation Matrix. An Expectation Matrix is a matrix where columns relate to manipulating variables (MVs) and rows to controlled variables (CVs). The elements of the matrix contain “Strong positive gain”, “Positive gain”, “Strong negative gain”, “Negative gain”, “Not sure” or “Empty”. A “strong positive gain” element means that a strong model with a positive gain is expected for the corresponding MV and CV; a “positive gain” element means that a normal model with positive gain is expected between the corresponding MV and CV. Similarly, a “strong negative gain” element means that a strong model with a negative gain is expected; a “negative gain” element means that a normal model with negative gain is expected. A “Not sure” element means that the user is unsure about the existence of a model for the corresponding MV and CV; “Empty” means that the user is sure that no model exists between the MV-CV pair. A simplified Expectation Matrix can also be used that contains only four types of elements: “Positive gain”, “Negative gain”, “Not sure” and “Empty”. Note also that other symbols can be used, for example, “+” for “Positive gain”, “−” for “Negative gain”, “?” for “Not sure” and “0” for “Empty”.

Identification Preparation

Now the user will prepare the test. This is done as follows.
1) Define the MV list, DV (disturbance variable or feedforward variable) list and CV list. Specify the MV high-low limits and CV high-low limits. Specify the step sizes (amplitudes) for the test for all MVs (a step size is top/top amplitude of a test signal).
2) The user specifies the time to steady state of the process unit, the number of test signals needed. The test device will generate the signals and show them in a window. The user can assign each test signal to an MV. In a closed-loop test, a test signals can also be applied to a CV setpoint or limit.
3) Close some CV loops. If the test is for a new MPC controller, configure some PID controllers for some sensitive CVs, such as a tray temperature that should stay in a small range, a level of a small drum and a quality that should be controlled tightly. Often these controllers already exist. If the test is for the maintenance of an existing MPC controller, turn it on during the test. If only part of the existing MPC works properly, use that part during the test. Add some PID loops if necessary.

Now it is ready to start the test.

Online Automatic Test and Model Identification

During the test, the following tasks are performed by the testing device and by the model identification device:
1) Excite MVs (or step MVs, as traditionally called) and some of the CV setpoints according to the test signal move patterns and their step sizes.
2) Monitor the test and, if necessary, adjust the test for stable operation. This is done as follows. If all CVs stay in their normal operation ranges, continue the test and do nothing. If an open loop CV drifts away slowly, change the average setpoint of some relevant MVs according to the Expectation Matrix. If a CV (either open loop or closed-loop) bumps around and hits both the high and low limits, reduce the step sizes of some relevant MVs.
3) Online automatic model identification. After about 25% of the planed test time, identification will start using the data up to that moment and will repeat in a regular interval, e.g., one hour. The identification can also start on demand. The identified models are displayed in the form of step responses, frequency responses and upper bounds, and model simulation. Also model delay matrix and gains matrix can be show.
4) Online automatic model validation and, if necessary, adjusts the test for model quality. This is done as follows. Each model is graded as A (very good), B (good), C (marginal) and D (poor) using its upper error bound. Each time, the identification algorithm will calculate the model upper bounds for the current models and grade all models. If certain MVs have produced enough A and B models according to the Expectation Matrix, their step sizes will be reduced (in order to decrease disturbance to operation). In the mean time, the algorithm also calculates the future error bounds and future grades at the end of the planed test. If future grades indicate that certain expected models cannot reach A or B grades at the end of the test, the step sizes of corresponding MVs will be increased in order to increase the signal-to-noise ratios for the models. Each MV step sizes are constrained by their corresponding limits. The testing device can also modify the test signal switch time for improving data quality. Increasing the switch time will increase the model quality at low frequencies; decreasing the switch time will increase the model quality at high frequencies.
5) Stop the test when most, say, 80% of expected models have reached A or B grades. Export models in a given format for use in the MPC control. The real test time can be shorter or longer than the planed test time.

### BRIEF DESCRIPTION OF THE DRAWINGS

FIG. 1 shows the general block diagram of the invention. It consists of a Testing device and an Identification device. The two devices are interconnected; the testing device is interconnected to the process unit (usually via DCS and PLC).

FIG. 2 shows the composition of a typical test signal. It the summation of a GBN signal and a white noise signal.

FIG. 3 shows the flow diagram in the Testing device for each tested MVs.

FIG. 4 shows the connection of the Testing device to process unit for an open loop test.

FIG. 5 shows the connection of the Testing device to process unit and to controller for a partial closed-loop test.

FIG. 6 shows the connection of the Testing device to process unit and to controller for an MPC closed-loop test.

FIG. 7 shows model identification procedure of the Identification device.

### DETAILED DESCRIPTION OF THE INVENTION

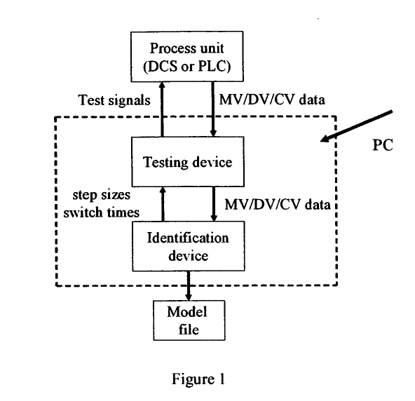

FIG. 1 shows the general block diagram of the invention. Nowadays process units use distributed control systems (DCS) as their instrumentation and regulatory control. In the illustrations and diagrams, we will assume that the given process unit is under DCS control, although the invention can also work with other instrumentation systems, such as programmable logic control (PLC) systems, or supervisory control and data acquisition (SCADA) systems. The computer apparatus for online automatic identification will be typically located in a personal computer (PC) using Microsoft Windows® operating system, although it can also be located in other kind of computers using other operating systems such as Linux and UNIX. The computer apparatus for online automatic identification consists of two parts: a testing device and a model identification device.

The Testing Device in FIG. 1 performs plant test by applying test signals or perturbations primarily at process MVs in order to excite process for model identification. The process MV, DV and CV data are stored in a database to be used by the Model Identification Device. After about 25% of the planed test time, the model identification device will be started automatically or manually (pressing a key). The model identification device will compute process models, calculate model step responses and frequency responses, perform model validation, and determine new desired step sizes of each test signals. All steps of identification device are performed automatically with no user intervention. The resulting models can be exported in a model format for certain MPC controller; the new desired step sizes of test signals will be sent to the testing device for adjusting the test.

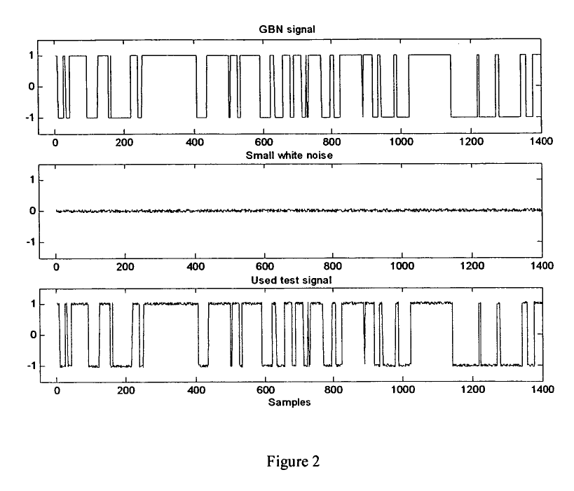

Before starting the test, the user needs to specify process time to steady state, or, settling time. Then, test signals will be created. A typical test signal used in the invention is the summation of a generalized binary noise (GBN) (Tulleken, 1990) and a small white noise. FIG. 2 shows the trend plot of a test signal. The guideline for designing the GBN part of the signals can be found in Zhu (2001, Chapter 3). Normally, the test signals are not correlated by design. However, for certain ill-conditioned processes such as high purity distillation columns, strongly correlated test signals will be used for some MVs; see Zhu (2001, Chapter 10). The user also needs to set a step size high limit for each test signals. These limits can be obtained from pre-test and from operation knowledge of the process unit.

A test time Tₜₑₛₜ will also be calculated for use in model validation purpose. The test time is an estimate of the test time needed for the given plant test. Denote Tₛₑₜₜₗₑ as the time to steady state or settling time, m as the number of MVs in the test, the formula for calculating Tₜₑₛₜ is

$${T}_{test} = \{ \begin{matrix}15 {T}_{settle} & for m \leq 10 \\ [ 1 + 0.1 ( m - 10 ) ] 15 {T}_{settle} & for m > 10\end{matrix} \qquad ( 1 )$$

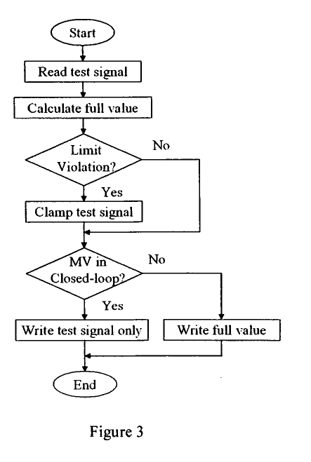

The testing device, when turned on, applies the designed test signals at process MVs and possibly some CV setpoints or CV limits in a real time manner that works at a constant sampling time, say, 1 minute. This testing sampling time can be the equal or greater than the MPC controller sampling time. FIG. 3 shows the flow diagram of the testing task for each tested MV at a sampling interval.

One important feature of the current invention is that many MVs are tested (moved) simultaneously. This number can be 10, 20, 30 or more than 50.

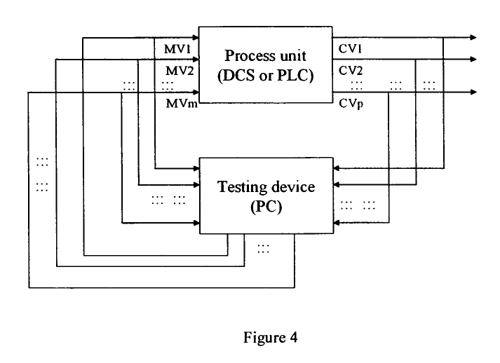

Another advantage of the present invention is its ability to use closed-loop test as well as open test. In an open loop plant test, all CVs of the MPC controller are in open loop mode, namely, none of the CVs is controlled. In an open loop test, test signals are applied at MVs. FIG. 4 shows the connection between the testing device and the process unit in an open loop test. In an open loop test, the testing device writes the full values to the tested MVs.

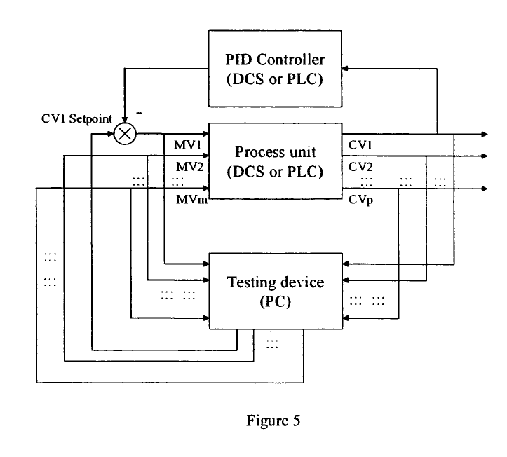

In a partial closed-loop test, PID controllers control some sensitive CVs; the rest of the CVs are in open loop. In a partial closed-loop test, test signals are applied at open loop MVs; for those closed-loop CVs, the test signals are usually applied at CV setpoints. FIG. 5 shows the connection between the testing device and the process unit in a partial closed-loop test where CV1 is controlled by a PID controller using MV1.

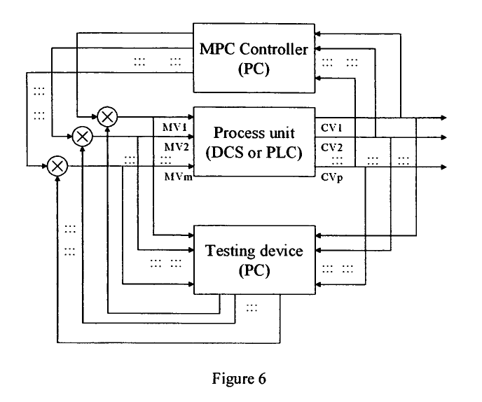

During an MPC closed-loop plant test, an MPC controller controls part or all the CVs. In an MPC closed-loop test, test signals are usually applied at MVs. Test signals can also be applied to some CV setpoints and/or CV limits. FIG. 6 shows the connection between the testing device and the process unit in an MPC closed-loop test.

For understanding various test types, it is useful to distinguish two parts of an MV value: 1) mean value or nominal value, the MV value without applying the test signal, 2) test signal, the perturbation added to the MV during the test. During the test, the relation is:
Full MV value=Mean value+Test signal (2)
When an MV is in open loop mode, the testing device will write the full MV value; see FIG. 4. When an MV is in MPC closed-loop, the testing device will write the test signal only and the MPC controller will write the mean value. The full MV value is obtained using a summer block; see FIG. 6. When a CV is in PID closed-loop control, the test device will write the full value of the CV setpoint; see FIG. 5.

Because the testing device is connected directly to the DCS or PLC, it is independent of the MPC controller and can work with any given MPC controller. It should be clear that we could also use mixed PID and MPC closed-loop test where some process CVs are controlled by an MPC controller and some by PID controllers.

When an MV is in closed-loop control, its movement consists of the test signal and controller action. Because the controller action of one MV can be correlated to the unmeasured disturbances and to other MVs, MVs in a closed-loop test will be, in general, correlated with each other and with unmeasured disturbances. The current invention can use correlated MV data in model identification.

In plant test, one needs to strike a balance between two conflicting gaols: 1) to excite the process for generating informative data about the process dynamic behaviour, and 2) to minimize disturbance caused by the test signals. The ability of using closed-loop test and closed-loop identification by the invention plays a key role in solving the two problems, because: 1) it is well know that closed-loop test can reduce disturbance to the process unit operation, and 2) it can also be shown that process data from a closed-loop test can lead to better models for closed-loop control; see Hjalmarsson et. al. (1996), Koung and MacGregor (1993), Jacobsen (1994) and Zhu (2001, Chapter 10). Besides, the testing device uses several other intelligent testing functionalities to meet the two goals, which are explained here.

Control action during plant test. If a CV is under closed-loop control, the underline controller will control it during the test. However, the testing device can also do some control in order to stabilize unit operation as follows:
1) Control for slow CV drifts. This is only done for open loop CVs. If an open loop CV is drifting away and is outside its high (low) limit, find its strong MV's according to the expectation matrix and change their average values in order to bring it back (according to the signs of the expectation matrix). The amount of change for each MV is
   (50% of its current step size)/(number of strong MV's)
Perform this action once each 0.3*Tₛₑₜₜₗₑ until the CV is back within the limit. Here Tₛₑₜₜₗₑ is the process time to steady state.
2) Control for bumping CVs. This is for both open loop and closed-loop CVs. If a CV is bumping around and hits both high and low limits, find its strong MV's and reduce their step sizes. The amount of step size reduction for each MV is
   (50% of its current step size)/(number of strong MV's)
Perform this action once each 0.3*Tₛₑₜₜₗₑ until the CV stopped bumping against high/low limits. Here Tₛₑₜₜₗₑ is the process time to steady state.

If necessary, appropriate control actions can also be done manually.

Test signals step size adjustment. Model identification device will not only produce process models, it will also provide information for step size changes for the ongoing plant test. For a given MV, if all its expected models are with good quality, the MV step size can be reduced in order to reduce disturbance to process unit; if some model quality will not be good enough at the end of the test, the MV step size will be increased in order to improve signal to noise ratio in the data. The text on model identification device will explain how to determine model quality. The testing device will implement the step changes, provided that they do not violate MV limits. Step changes can also be done manually.

Test signal switch time adjustment. The frequency content or power spectrum of a test signal is mainly determined by the average switch time, or, average step length of the GBN signal. Increasing the average switch time will increase the signal power at lower frequencies and hence improve model quality at lower frequencies. Similarly, decreasing the average switch time will increase the signal power at higher frequencies and hence improve model quality at higher frequencies. Hence, for an MV, if the corresponding model quality needs to be improved only at lower frequencies, the testing device will increase the average switch time, typically, double it; if the corresponding model quality needs to be improved only at higher frequencies, the testing device will decrease the average switch time, typically, halve it. Test signal switch time can be adjusted automatically by the testing device, or, manually.

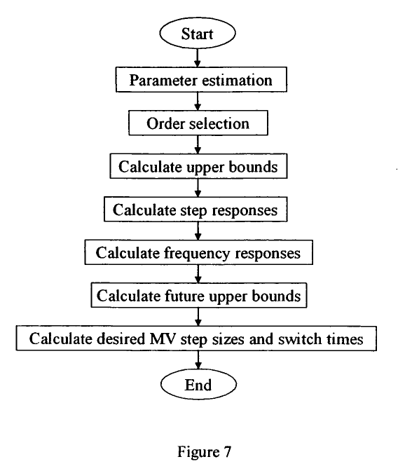

Model identification device performs model identification, model validation and other related computations using most recent MV, DV and CV data available. FIG. 7 shows the flow diagram of model identification device. The identification algorithms used in the device is based on the asymptotic method (ASYM) developed in Zhu (1998, 2001). The following gives a description of the methodology.

Given a multivariable process with m MVs and p CVs. DVs will be treated as MVs in model identification. Assume that a linear discrete-time process generates the data as
y(t)=G^{o}(z⁻¹)u(t)+H^{o}(z⁻¹)e(t) (3)
where u(t) is an m-dimensional input vector, y(t) is a p-dimensional output vector, G^{o}(z⁻¹) is the true process model and z⁻¹ is the unit time delay operator. H^{o}(z⁻¹)e(t) represents the unmeasured disturbances acting at the outputs, and e(t) is a p-dimensional white noise vector. Denote the data sequence that is collected from an identification test as
Z^{N}:={u(1),y(1),u(2),y(2), . . . ,u(N),y(N)} (4)
where N is the number of samples at the current time.

The model to be identified is in the same structure as in (3):
y(t)=G(z⁻¹)u(t)+H(z⁻¹)e(t) (5)

The process model G(z⁻¹) and noise filter H(z⁻¹) will be parametrized in matrix fraction description (MFD); see Zhu (2001) for details. The model will be calculated by minimizing the prediction error cost function; see Ljung (1985).

The frequency response of the process and that of the model are denoted as
T^{o}(e^{iω}):=col[G^{o}(e^{iω}),H^{o}(e^{iω})]
\hat{T}ⁿ(e^{iω}):=col[Ĝⁿ(e^{iω}),Ĥⁿ(e^{iω})]
where n is the degree of the polynomials of the model, col(.) denotes the column operator.

Under some conditions of model order and structure and test signals, the following asymptotic results on the model properties in the frequency domain can be shown (Ljung, 1986 and Zhu, 1989)
\hat{T}ⁿ(e^{iω})→T^{o}(e^{iω}) as N→∞ (Consistence) (6)

The errors of \hat{T}ⁿ(e^{iω}) follow a Gaussian distribution, with covariance as
cov[\hat{T}ⁿ(e^{iω})≈n/NΦ^{-T}(ω) [symbol] Φᵥ(ω) (7)
where Φ(ω) is the spectrum matrix of inputs and prediction error residual col[u^{T}(t), ξ^{T}(t)], Φᵥ, (ω) is spectrum matrix of unmeasured disturbances, [symbol] denotes the Kronecker product and −T denotes inverse and then transpose. This theory holds for data created by both open loop tests and closed-loop tests.

In the following, we will outline the model identification method using the asymptotic theory.

Parameter Estimation

A) Estimate a high order ARX (equation error) model
Âⁿ(z−1)y(t)=\hat{B}ⁿ(z⁻¹)u(t)+ê(t) (8)

where Âⁿ(z⁻¹) is a diagonal polynomial matrix and \hat{B}ⁿ(z⁻¹) is full polynomial matrix, both with degree n polynomials. Denote Ĝⁿ(z⁻¹) as the high order ARX model of the process, and Ĥⁿ(z⁻¹) as the high order model of the disturbance.

B) Perform frequency weighted model reduction

The high order model in (8) is unbiased, provided that the process behaves linear around the working point. The variance of this model is high due to its high order. Here we intend to reduce the variance by perform a model reduction on the high order model. Using the asymptotic result of (6) and (7), one can show that the asymptotic negative log-likelihood function for the reduced process model is given by (Wahlberg, 1989, Zhu and Backx, 1993)

$$V = {\sum }_{i = 1}^{p} {\sum }_{j = 1}^{m} {\int }_{- π}^{π} \vert \{ {\vert {\hat{G}}_{ij}^{n} ( ω ) - {\hat{G}}_{ij} ( ω ) \vert}^{2} \frac{1}{{[ {Φ}^{- 1} ( ω ) ]}_{ij} {Φ}_{{v}_{i}} ( ω )} \} \vert ⅆ ω \qquad ( 9 )$$

The reduced model Ĝ(z⁻¹) is thus calculated by minimizing (9) for a fixed order. The same can be done for the disturbance model Ĥⁿ(z⁻¹)=1/Âⁿ(z⁻¹).

Order Selection

The best order of the reduced model is determined using a frequency domain criterion ASYC; see Zhu (1994) for the motivation and evaluation. The basic idea of this criterion is to equalise the bias error and variance error of each transfer function in the frequency range that is important for control. Let [0, ω₂] defines the frequency band that is important for the MPC application, the asymptotic criterion (ASYC) is given by:

$$ASYC = {\sum }_{i = 1}^{p} {\sum }_{j = 1}^{m} {\int }_{0}^{{ω}_{2}} \vert [ {\vert {\hat{G}}_{ij}^{n} ( ω ) - {\hat{G}}_{ij} ( ω ) \vert}^{2} - {\frac{n}{N} [ {Φ}^{- 1} ( ω ) ]}_{jj} {Φ}_{{v}_{i}} ( ω ) ] \vert ⅆ ω \qquad ( 10 )$$

Delay Estimation

Delays often exist in process units. Good delay estimation can improve model accuracy. Delays are estimated by trying various delays in model identification for a fix order. The delays that minimize the simulation error loss function will be used. The loss function for selecting the best delays is

$${\sum }_{i = 1}^{p} {\vert {y}_{i} ( t ) - {\hat{y}}_{i} ( t ) \vert}^{2} \qquad ( 11 )$$

where ŷ,(t) is the simulated CVi using the model with delays.

Error Bound Matrix for Model Validation

According to the result (4) and (5), a 3σ bound can be derived for each transfer function of the high order model as follows:

$$\vert {G}_{ij}^{o} ( {ⅇ}^{i ω} ) - {\hat{G}}_{ij}^{n} ( {ⅇ}^{iω} ) \vert \leq {BND}_{ij} = 3 \sqrt{{\frac{n}{N} [ {Φ}^{- 1} ( ω ) ]}_{jj} {Φ}_{{v}_{i}} ( ω )} w . p .99 .9 \% \qquad ( 12 )$$

We will also use this bound for the reduced model because the model reduction will in general improve model quality.

The upper bound will be used to quantify the quality of each model. Grade the model according to the relative size of the error bound and the model frequency response over the low and middle frequencies. A model is graded as ‘A’ (very good), if bound≦30% model, ‘B’ (good), if 30% model<bound≦60% model, ‘C’ (marginal), if 60% model<bound≦90% model, and ‘D’ (poor, or, no model), if bound>90% model. This grading system can be adjusted for the given class of applications. The above grading is suitable for MPC application for the refining and petrochemical industries.

Model validation using the grading system is done as follows:

If most, say 80%, of the expected models are with ‘A’ and ‘B’ grades, the rest of the expected models are with C grade, models can be used in the MPC controller and identification test can be stopped.

If the above condition is not met, continue the test and, possibly, adjust the ongoing test.

As mentioned before, test adjustment includes change MV step sizes, average switch time of GBN signals. The required changes are obtained using the so-called future upper bounds, the estimated upper bounds at the end of the test. Denote Nₜₑₛₜ as the number of samples at the end of the test, the future upper bound for a model is

$${BND}_{ij}^{Future} = 3 \sqrt{{\frac{n}{{N}_{test}} [ {Φ}^{- 1} ( ω ) ]}_{jj} {Φ}_{{v}_{i}} ( ω )} \qquad ( 13 )$$

The grading results using the future upper bounds will be called future grades.

Test adjustment is done as follows:
For a given MV, if the future grades of the expected models are mostly ‘A’ and ‘B’, the MV step size is proper. No change is needed.
For a given MV, if the future grades of many expected models are ‘C’ and ‘D’, increase its step sizes so that they become ‘A’ or ‘B’ grade.
For a given MV, if the future grades of many expected models are ‘C’ and ‘D’, increase the MV step size so that the future grades become ‘A’ or ‘B’ grade. The corresponding upper bound is inversely proportional to the MV step size; see Zhu (2001, Chapter 6 and 7.)
For a given MV, if the future grades of many expected models are ‘C’ and ‘D’ and the MV step size already at its high limit, increase the average switch time of the MV test signal; usually double it.
For a given MV, if the future grades of the expected models are mostly ‘A’, the MV step size can be reduced somewhat; usually 30 to 50%.

The computation of the test adjustments is done in the model identification device and the results are passed to the testing device for implementation.

Use Expectation Matrix in Model Identification

The Expectation Matrix provides information about the locations of models between MVs and CVs. When using the Expectation Matrix in identification, only expected models between certain MVs and CVs will be identified; unexpected models corresponding to the empty elements of the Expectation Matrix will be excluded. Compared with identifying the full models between all MVs and all CVs, the use of Expectation Matrix will reduce the number of parameters considerably, which can lead to higher model accuracy and can also increase the speed of computation.

The use of Expectation Matrix in model identification is optional. When an Expectation Matrix is not available or not reliable, the full models will be identified. Note that an Expectation Matrix can be created or modified using the identification results of full models.

### CITED LITERATURE

Hjalmarsson, H., M. Gevers, F. de Bruyne (1996). For model-based control design, closed-loop identification gives better performance. Automatica, Vol. 32, No. 12, pp. 1659-1673.
Jacobsen, E. W. (1994). Identification for Control of Strongly Interactive Plants. Paper 226ah, AIChE Annual Meeting, San Francisco.
Koung, C. W. and J. F. MacGregor (1993). Design of identification experiments for robust control. A geometric approach for bivariate processes. Ind. Eng. Chem. Res., Vol. 32, pp. 1658-1666.
Ljung, L. (1985). Asymptotic variance expressions for identified black-box transfer function models. IEEE Trans. Autom. Control, Vol. AC-30, pp. 834-844.
Ljung. L. (1987). System Identification: Theory for the User. Prentice-Hall, Englewood Cliffs, N.J.
Ljung, L. and Z. D. Yuan (1985). Asymptotic properties of black-box identification of transfer functions. IEEE Trans. Autom. Control, Vol. AC-30, pp. 514-530.
Qin, S. J. and Badgwell, T. J. (1997). An overview of industrial model predictive control technology. Chemical Process Control-V, edited by J. C. Kantor, C. E. Garcia and B. Carnahan, pp. 232-256. Tahoe, Calif.
Richalet, J. (1993). Industrial applications of model based predictive control. Automatica, Vol. 29, No. 5, pp. 1251-1274.
Tulleken, H. J. A. F. (1990). Generalized binary noise test-signal concept for improved identification-experiment design. Automatica, Vol. 26, No. 1, pp. 37-49.
Wahlberg, B. (1989). Model reduction of high-order estimated models: the asymptotic ML approach. Int. J. Control, Vol. 49, No. 1, pp.169-192.
Zhu, Y. C. (1998). Multivariable process identification for MPC: the asymptotic method and its applications. Journal of Process Control, Vol. 8, No. 2, pp. 101 -115.
Zhu, Y. C. (2001). Multivariable System Identification for Process Control. Elsevier Science, Oxford.

1. Computer apparatus that performs online and automatic identification of dynamic process models for use in model predictive control (MPC) and other advanced process control (APC) compromising:
a testing device that carries out the plant test automatically and collects process data; and
a model identification device that carries out model identification and validation and adjust the test parameters automatically using collected process data.

2. Computer apparatus as claimed in claim 1 wherein the testing device and the model identification device are interconnected seamlessly so that the whole identification procedure including plant test and model identification (computation) is done online and automatically.

3. Computer apparatus as claimed in claim 1 wherein the testing device uses automated multivariable plant test that move many or all MVs simultaneously.

4. Computer apparatus as claimed in claim 1 wherein the testing device uses closed-loop control during the test in order to reduce disturbance to unit operation and the controller can be of any type that includes regulatory PID controllers, any MPC controller, or the combination of the two types.

5. Computer apparatus as claimed in claim 1 wherein the testing device will continue testing when the MPC controller is taking control actions.

6. Computer apparatus as claimed in claim 1 wherein the testing device uses test signals that are related to unit time to steady state. The planned test time is related to the process time to steady state and the number of MVs.

7. Computer apparatus as claimed in claim 1 wherein the testing device uses GBN (generalised binary noise) signals in the plant test for the identification of linear models. A small white noise signal is added to each GBN signal to improve its information content. Normally, the test signals are not correlated by design. However, for certain ill-conditioned processes such as high purity distillation columns, strongly correlated test signals will be used for some MVs.

8. Computer apparatus as claimed in claim 1 wherein the testing device can control open loop CVs by move the mean values of some open loop MVs in order to reduce process disturbance. The testing devise can reduce MV step sizes in order to reduce process disturbance.

9. Computer apparatus as claimed in claim 1 wherein the testing device adjusts test signal step size and test signal switch time during the plant test in order to improve model quality.

10. Computer apparatus as claimed in claim 1 wherein the testing device uses specially designed graphic user interfaces (GUIs) for test monitoring. The MV Window shows both past MV movements and future planed movements. The CV Window shows past CV movements and it will also show predicted CV movements if a model is identified and available.

11. Computer apparatus as claimed in claim 1 wherein the model identification device uses the ASYM method in model parameter estimation and order selection.

12. Computer apparatus as claimed in claim 1 wherein the model identification device calculates current upper bounds and future upper bounds of model errors.

13. Computer apparatus as claimed in claim 1 wherein the calculated upper error bounds are used to grade model qualities, to adjusting the ongoing plant test and to decide the stop time of the plant test.

14. Computer apparatus as claimed in claim 1 wherein the model identification device uses truly closed-loop data for identification, that is, the data contain feedback actions of the PID or MPC controller and the test signal.

15. Computer apparatus as claimed in claim 1 wherein the model identification device uses the Expectation Matrix in model identification in order to improve computation speed and model quality.

16. Computer apparatus as claimed in claim 1 wherein the model identification device estimates process delays (dead times) in order to improve model quality.
